(19) United States
(12) Patent Application Publication
(10) Pub. No.: US 2024/0404803 A1
(43) Pub. Date: Dec. 5, 2024

(54) MICROWAVE PRECLEAN APPARATUS AND PROCESSING METHOD FOR IMPURITY REMOVAL

(71) Applicant: Applied Materials, Inc., Santa Clara, CA (US)

(72) Inventors: Yoon Ah SHIN, Santa Clara, CA (US); Jiajie CEN, Santa Clara, CA (US); Zhiyuan WU, San Jose, CA (US); Bencherki MEBARKI, Santa Clara, CA (US); Kevin KASHEFI, Dublin, CA (US); Joung Joo LEE, San Jose, CA (US); Xianmin TANG, San Jose, CA (US)

(21) Appl. No.: 18/647,819

(22) Filed: Apr. 26, 2024

Related U.S. Application Data
(60) Provisional application No. 63/470,709, filed on Jun. 2, 2023.

(51) Int. Cl. H01J 37/32

(52) U.S. Cl. CPC H01J 37/32853; H01J 37/32201; H01J 37/32357

(57) ABSTRACT

Embodiments of the present disclosure generally relate to a low temperature non-plasma containing preclean process to selectively remove contaminants from the surface of a substrate, such as halogen containing and/or metal oxide containing contaminants. The non-plasma containing precleaning process is performed at a low temperature by use of a microwave source that is configured to provide microwave energy to the processing gases disposed within a processing chamber. The non-plasma low temperature preclean process is effective in reducing halogen containing residues, such as fluorine and chlorine containing residues formed on a surface of a substrate.

### CROSS-REFERENCE TO RELATED APPLICATIONS

This application claims priority to U.S. Provisional Patent Application No. 63/470,709, filed Jun. 2, 2023, entitled “MICROWAVE PRECLEAN APPARATUS AND PROCESSING METHOD FOR IMPURITY REMOVAL”, assigned to the assignee hereof, the contents of which is hereby incorporated by reference in its entirety.

### BACKGROUND

### Field

Embodiments described herein generally relate to semiconductor device fabrication. More specifically, embodiments of the present disclosure relate to microwave sources used in one or more semiconductor device containing substrate processing steps, such as a cleaning process performed at low temperatures.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

In fabrication of an integrated circuit, middle-end-of-line (MEOL) and back-end-of-line (BEOL) stages may include forming gate regions of transistors and local interconnect layers with molybdenum (Mo). Conventionally, a surface of a metal layer or a dielectric layer is pre-cleaned to remove metal oxides, such as molybdenum oxide (MoOx) and tungsten oxide (WOx), and reduce chlorine or fluorine residues from an etching process by a selective etch at a high temperature around 450° C. However, the conventional etch process, which is performed at such high temperatures, typically recesses an underlying metal layer undesirably, causing a bottom void in a BEOL process. Chlorine or fluorine residues that are not removed may degrade dielectric layers, which also leads to a short margin concern.

Therefore, there is a need for methods of removing metal oxides, such as molybdenum oxide (MoOx) and tungsten oxide (WOx), without damaging an underlying layer and reducing chlorine or fluorine residues.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure include a method of processing a substrate, comprising: positioning a substrate within a processing chamber that comprises a microwave source; flowing a process gas that comprising hydrogen into the processing chamber; and delivering microwave energy to the processing gas, wherein delivering the microwave energy to the process gas does not generate a plasma in the processing chamber. A substrate temperature is maintained at a temperature below approximately 300° C. while the flowing the process gas and the delivering the microwave energy; and the flowing the process gas and the delivering microwave energy is configured to remove a halogen containing material from a surface of the substrate and/or a metal oxide from the surface of the substrate.

Embodiments of the disclosure may also include a method of processing a semiconductor structure formed in a substrate, comprising: exposing a feature formed within a substrate to a preclean process. The preclean process may comprise: positioning a substrate within a processing chamber that comprises a microwave source; flowing a process gas that comprising hydrogen into the processing chamber; delivering microwave energy, from the microwave source, to the processing gas, wherein delivering the microwave energy to the process gas does not generate a plasma in the processing chamber; and maintaining the substrate at a temperature below 300° C.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2 is a flow diagram depicting a method of filling a feature in a semiconductor structure using a liner layer and an interruption layer, according to one or more of the embodiments described herein.

FIG. 3A is a schematic of a processing chamber that includes a microwave source, in accordance with an embodiment.

FIG. 3B is a schematic of a solid state microwave emission module, in accordance with an embodiment.

FIG. 3C is a perspective view illustration of a source array for a microwave source, in accordance with an embodiment.

FIG. 3D is a cross-sectional illustration of a processing chamber for processing a substrate, in accordance with an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the present disclosure generally relate to a low temperature non-plasma containing preclean process to selectively remove contaminants from the surface of a substrate, such as halogen containing and/or metal oxide containing contaminants. The non-plasma containing precleaning process is performed at a low temperature of between about 100° C. and about 300° C., for example, between about 200° C. and about 270° C., or even between about 210° C. and about 270° C., by use of a microwave source that is configured to provide microwave energy to the processing gases disposed within a processing chamber. The non-plasma low temperature preclean process is effective in reducing halogen containing residues, such as fluorine and chlorine containing residues formed on a surface of a substrate.

### Processing System Example

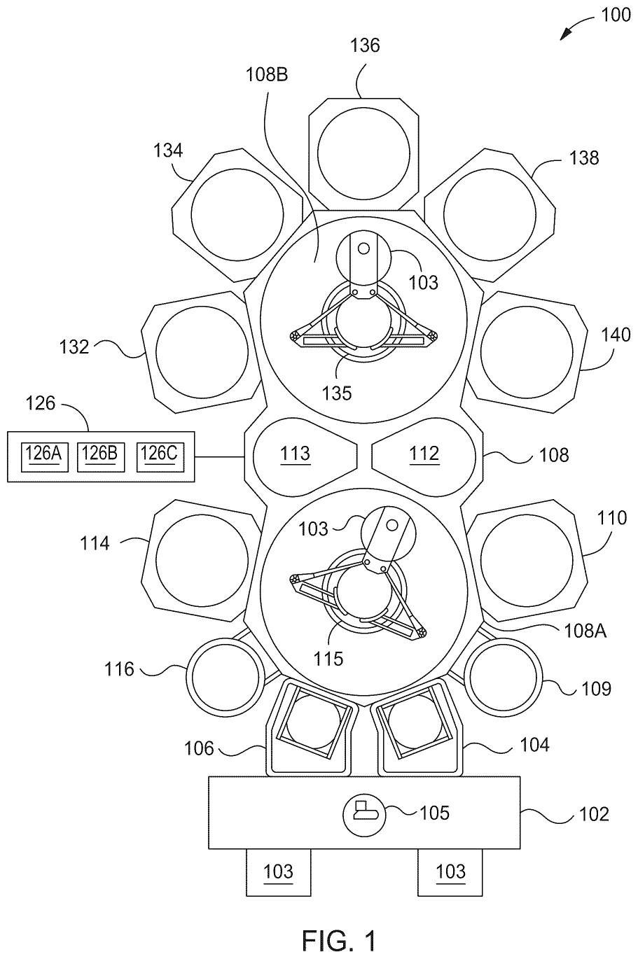

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 110, a precleaning process is performed in chamber 114, and one or more of a deposition, an etching, and/or a thermal processing process is performed in at least one of the chambers 132, 134, 136, 138, and 140. In one example, the remote plasma (RPS) assisted process performed in chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 110 and 114, and one or more of a deposition, an etching, and/or a thermal processing process is performed in at least one of the chambers 132, 134, 136, 138, and 140. In one example, the processing chambers 132, 134, 136, 138, or 140 may be a Volta™ CVD/ALD chamber, or Encore™ PVD chambers available from Applied Materials of Santa Clara, Calif.

### Substrate Processing Sequences

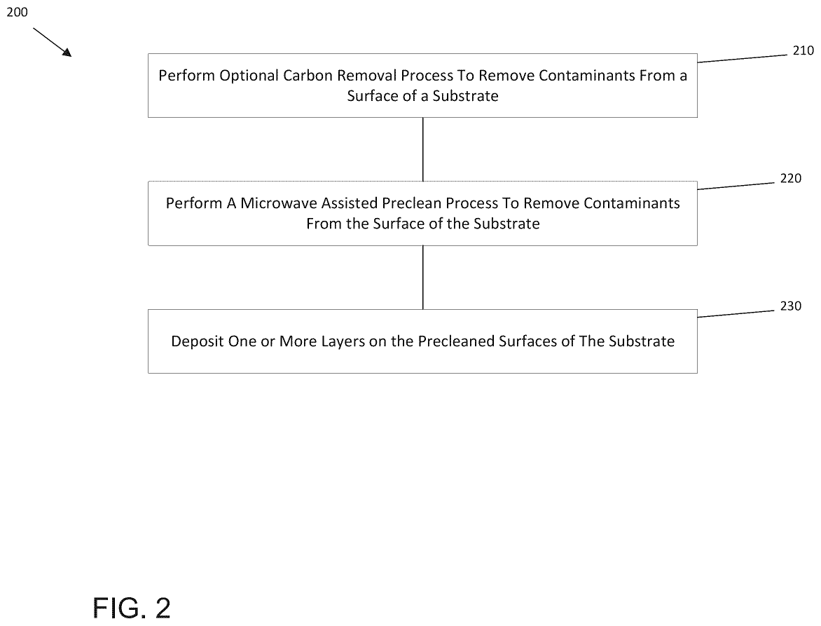

FIG. 2 depicts a process flow diagram of a method 200 of processing a substrate to, for example, form MEOL and BEOL structures, according to one or more embodiments of the present disclosure. The method 200 will include a pre-clean process that is configured to clean portions of a feature formed in a surface of a substrate. In some configurations the feature will include one or more dielectric containing surfaces and one or more metal containing surfaces, such as a metal surface that comprises a metal (e.g., molybdenum (Mo), tungsten (W), tungsten carbide (WC), or tungsten nitride (WN)). At the beginning of the method 200 the one or more metal containing surfaces will typically include a metal oxide containing surface, such as a molybdenum oxide (MoOx) or a tungsten oxide (WOx) containing surface.

The method 200 begins with block 210, in which an optional carbon removing pretreatment is performed on the substrate to remove any residual carbon containing materials from the surface of the substrate. In some embodiments, the optional carbon removing pretreatment includes the delivery of hydrogen radicals to the surface of the substrate by use of an RPS source treatment process performed in a first processing chamber (e.g., chamber 110). In one example, the RPS source treatment process is performed in an APC chamber at a temperature of about 345° C., and a 300 mTorr chamber pressure for about 25 seconds. The process is performed to remove impurities from a surface of a metal layer and a surface of an adjacent dielectric layer within a feature formed in the substrate. In some other embodiments of processes performed during block 210, the optional carbon removing pretreatment process includes the delivery of a process gas (e.g., hydrogen containing gas) to a processing region of a process chamber (e.g., chamber 110, 114) and delivering microwave energy to the process gas to excite the process gas and remove carbon containing contaminants from the substrate surface. In either case, it is often desirable to avoid forming a plasma over the surface of the substrate to avoid the ions generated in the plasma causing damage to the material layers found on the substrate surface. The microwave delivery process can include delivering 125 Watts of microwave energy while the chamber is maintained at a pressure of between 20 mTorr and 60 mTorr and a flow rate of between 5 and 50 sccm of molecular hydrogen (H₂) is flowed in the chamber. In an embodiment, the high-frequency electromagnetic radiation provided from a microwave source may have a frequency between approximately 300 MHz and 1000 GHz, such as between approximately 1 GHz and 300 GHz.

Next at block 220, a preclean process is performed on the substrate to remove any residual halogen containing materials and/or any metal oxide containing materials from the surface of the substrate by use of a low temperature non-plasma microwave assisted process. In some other embodiments, the precleaning process includes the delivery of a process gas (e.g., hydrogen containing gas) to a processing region of a process chamber (e.g., chamber 110, 114) and delivering microwave energy to the process gas to excite the process gas and remove the halogen containing and/or metal oxide containing contaminants from the substrate surface. It is desirable to avoid forming a plasma over the surface of the substrate during block 220 to avoid the ions that would be generated in the plasma from causing damage to the material layers found on the substrate surface. The microwave delivery process can include delivering 125 Watts of microwave energy while the chamber is maintained at a pressure of between 20 mTorr and 60 mTorr and a flow rate of between 5 and 50 sccm of molecular hydrogen (H₂) is flowed in the chamber. In an embodiment, the high-frequency electromagnetic radiation provided from a microwave source may have a frequency between approximately 300 MHz and 1000 GHz, such as between approximately 1 GHz and 300 GHz.

Next at block 230, a deposition process is performed on the substrate to form one or more metal layers over the surfaces precleaned during block 220. In some embodiments, the deposition process includes forming at least part of a metal contact structure. The method 200 may generally include, at block 230, forming a metal layer or substantially filling the feature formed in the substrate. In some embodiments, the activity performed in block 230 may be performed in part by using an ALD or CVD deposition process in a process chamber (e.g., chamber 132-140) that utilizes a metal containing precursor, such as a fluorine containing precursor, or a chlorine containing precursor that comprises a metal such as molybdenum or tungsten. In one or more embodiments, the introduced precursor may comprise or consist essentially of a fluorine-free metal halide. Examples of tungsten halides include, but are not limited to, tungsten pentachloride (WCl₅) and tungsten hexachloride (WCl₆). Examples of molybdenum halides include, but are not limited to, tungsten pentachloride (MoCl₅) and tungsten hexachloride (MoCl₆). In one or more embodiments, the fluorine-free tungsten precursor comprises or consists essentially of a molybdenum oxyhalide or tungsten oxyhalide precursor. Examples of a tungsten oxyhalide include, but are not limited to, tungsten oxytetrachloride (WOCl₄) and tungsten dichloride dioxide (WO₂Cl₂). In one or more embodiments, the fluorine-free tungsten precursor is also a chlorine-free tungsten precursor (CFW). Examples of a fluorine-free and chloride-free tungsten precursor includes, but is not limited to, tungsten pentabromide (WBr₅) and tungsten hexabromide (WBr₆).

In some embodiments, substantially filling the feature formed in the substrate with a conductive material includes exposing the precleaned surfaces to a precursor including hydrogen (H₂) and at least one of tungsten (VI) hexafluoride (WF₆) or tungsten (V) chloride (WCl₅). In some embodiments, substantially filling the feature with the conductive material includes depositing the conductive material by a CVD process. The CVD process may be performed in a processing chamber, such as the processing chamber 134, 136, 138, or 140 shown in FIG. 1. In some embodiments, the conductive material comprises tungsten (W) or molybdenum (Mo). In one example, forming the metal layer includes using a CVD process that includes the process parameters including a pressure of 1 mTorr to 500 Torr, a substrate temperature of 100° C. to 600° C., a period of time required to fill the feature, using precursor including at least one of MoCl₅, WF₆ or WCl₆, and a carrier gas (e.g., inert gas) in the presence of H₂.

### Processing Chamber Example.

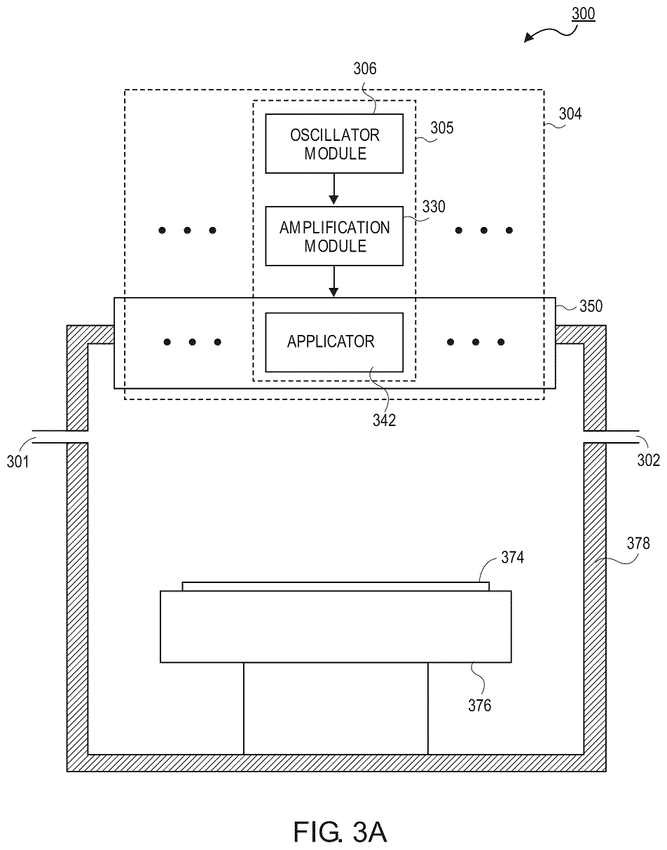

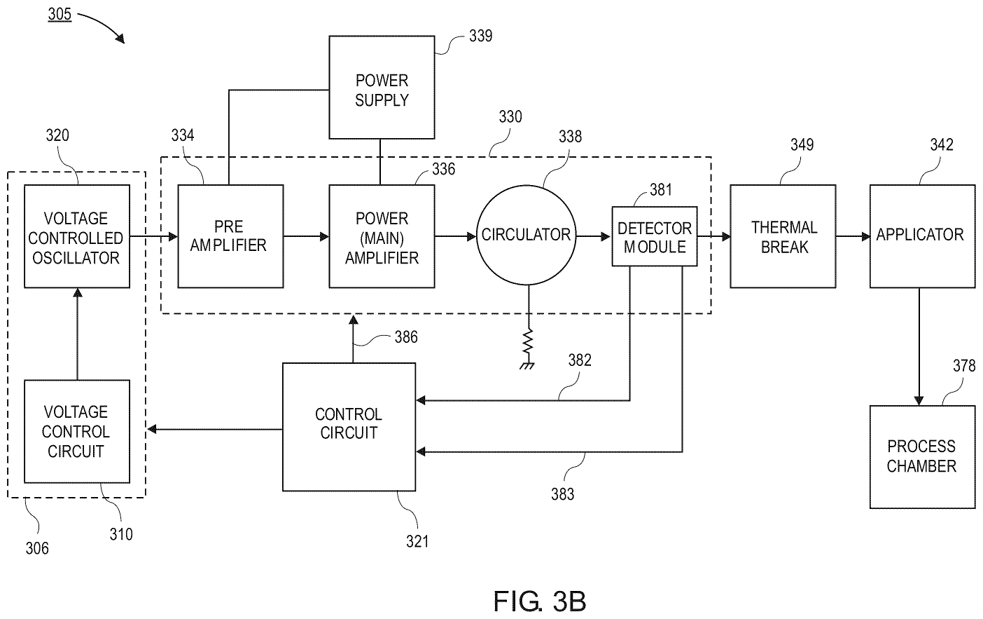

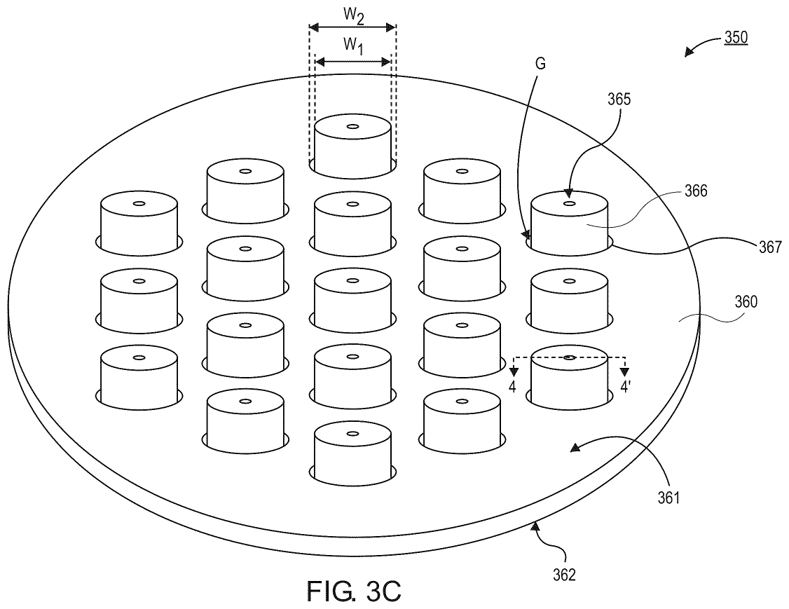

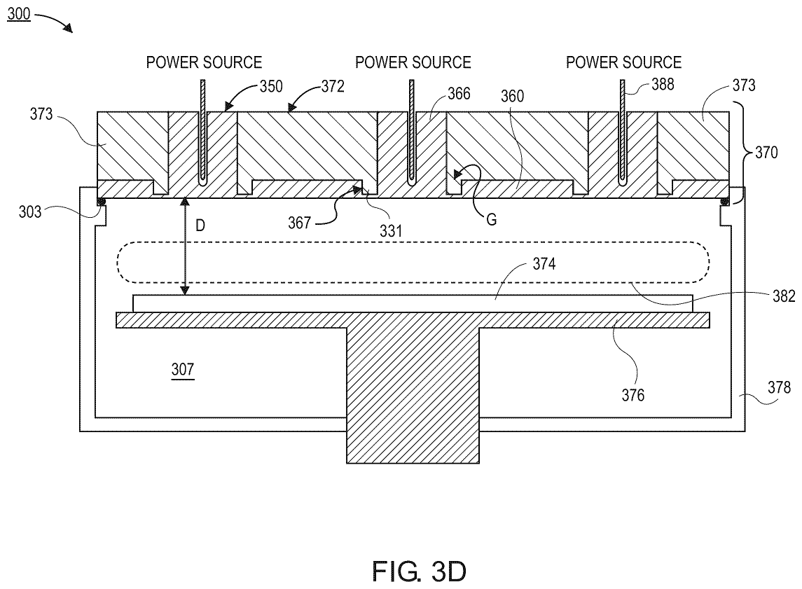

Referring now to FIGS. 3A-3D, a series of illustrations depicting an example of a microwave processing tool 300 is shown, in accordance with an embodiment. The microwave processing tool 300 is configured to deliver microwave energy to a processing region of the process chamber to perform a low temperature preclean process on a substrate.

Referring now to FIG. 3A, a cross-sectional illustration of a microwave processing tool 300 (referred to as processing tool 300 for short) is shown, according to an embodiment. In some embodiments, the processing tool 300 may be a processing tool suitable for any type of processing operation that requires the delivery of microwave energy. In some embodiments, one or more of the chambers 110 and 114, or even chambers 132-140, may include the processing tool 300. The processing tool may emit high-frequency electromagnetic radiation in the form of microwave energy. In some embodiments, “High-frequency” may refer to frequencies between 300 MHz and 1000 GHz.

Generally, embodiments include a processing tool 300 that includes a chamber 378. In processing tool 300, the chamber 378 may be a vacuum chamber. A vacuum chamber may include a pump (not shown) for removing gases from the chamber to provide the desired vacuum. Additional embodiments may include a chamber 378 that includes one or more gas lines 301 for providing processing gasses into the chamber 378 and exhaust lines 302 for removing byproducts from the chamber 378. While not shown, it is to be appreciated that gas may also be injected into the chamber 378 through a source array 350 (e.g., as a showerhead) for evenly distributing the processing gases over a substrate 374.

In an embodiment, the substrate 374 may be supported on a chuck 376. For example, the chuck 376 may be any suitable chuck, such as an electrostatic chuck. The chuck 376 may also include cooling lines and/or a heater to provide temperature control to the substrate 374 during processing. Due to the modular configuration of the high-frequency emission modules described herein, embodiments allow for the processing tool 300 to accommodate any sized substrate 374. For example, the substrate 374 may be a semiconductor wafer (e.g., 200 mm, 300 mm, 450 mm, or larger). Alternative embodiments also include substrates 374 other than semiconductor wafers. For example, embodiments may include a processing tool 300 configured for processing glass substrates, (e.g., for display technologies).

According to an embodiment, the processing tool 300 includes a modular high-frequency emission source 304. The modular high-frequency emission source 304 may comprise an array of high-frequency emission modules 305. In an embodiment, each high-frequency emission module 305 may include an oscillator module 306, an amplification module 330, and an applicator 342. As shown, the applicators 342 are schematically shown as being integrated into the source array 350.

In an embodiment, the oscillator module 306 and the amplification module 330 may comprise electrical components that are solid state electrical components. In an embodiment, each of the plurality of oscillator modules 306 may be communicatively coupled to different amplification modules 330. For example, each oscillator module 306 may be electrically coupled to a single amplification module 330. In an embodiment, the plurality of oscillator modules 306 may generate incoherent electromagnetic radiation. Accordingly, the electromagnetic radiation induced in the chamber 378 will not interact in a manner that results in an undesirable interference pattern.

In an embodiment, each oscillator module 306 generates high frequency electromagnetic radiation that is transmitted to the amplification module 330. After processing by the amplification module 330, the electromagnetic radiation is transmitted to the applicator 342. In an embodiment, the applicators 342 each emit electromagnetic radiation into the chamber 378. In some embodiments, the applicators 342 couple the electromagnetic radiation to the processing gasses in the chamber 378 to provide energy thereto, without forming a plasma.

Referring now to FIG. 3B, a schematic of a solid state high-frequency emission module 305 is shown, in accordance with an embodiment. In an embodiment, the high-frequency emission module 305 comprises an oscillator module 306. The oscillator module 306 may include a voltage control circuit 310 for providing an input voltage to a voltage controlled oscillator 320 in order to produce high-frequency electromagnetic radiation at a desired frequency. The voltage controlled oscillator 320 is an electronic oscillator whose oscillation frequency is controlled by the input voltage. According to an embodiment, the input voltage from the voltage control circuit 310 results in the voltage controlled oscillator 320 oscillating at a desired frequency.

According to an embodiment, the electromagnetic radiation is transmitted from the voltage controlled oscillator 320 to an amplification module 330. The amplification module 330 may include a driver/pre-amplifier 334, and a main power amplifier 336 that are each coupled to a power supply 339. According to an embodiment, the amplification module 330 may operate in a pulse mode. For example, the amplification module 330 may have a duty cycle between 1% and 99%. In a more particular embodiment, the amplification module 330 may have a duty cycle between approximately 15% and 50%.

In an embodiment, the electromagnetic radiation may be transmitted to the thermal break 349 and the applicator 342 after being processed by the amplification module 330. However, part of the power transmitted to the thermal break 349 may be reflected back due to the mismatch in the output impedance. Accordingly, some embodiments include a detector module 381 that allows for the level of forward power 383 and reflected power 382 to be sensed and fed back to the control circuit module 321. It is to be appreciated that the detector module 381 may be located at one or more different locations in the system (e.g., between the circulator 338 and the thermal break 349). In an embodiment, the control circuit module 321 interprets the forward power 383 and the reflected power 382, and determines the level for the control signal 385 that is communicatively coupled to the oscillator module 306 and the level for the control signal 386 that is communicatively coupled to the amplification module 330. In an embodiment, control signal 385 adjusts the oscillator module 306 to optimize the high-frequency radiation coupled to the amplification module 330. In an embodiment, control signal 386 adjusts the amplification module 330 to optimize the output power coupled to the applicator 342 through the thermal break 349. In an embodiment, the feedback control of the oscillator module 306 and the amplification module 330, in addition to the tailoring of the impedance matching in the thermal break 349, may allow for the level of the reflected power to be less than approximately 5% of the forward power. In some embodiments, the feedback control of the oscillator module 306 and the amplification module 330 may allow for the level of the reflected power to be less than approximately 2% of the forward power.

Accordingly, embodiments allow for an increased percentage of the forward power to be coupled into the processing chamber 378, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 3C, a perspective view illustration of a source array 350 is shown, in accordance with an embodiment. In an embodiment, the source array 350 comprises a dielectric plate 360. A plurality of cavities 367 are disposed into a first surface 361 of the dielectric plate 360. The cavities 367 do not pass through to a second surface 362 of the dielectric plate 360. The source array 350 may further include a plurality of dielectric resonators 366. Each of the dielectric resonators 366 may be in a different one of the cavities 367. Each of the dielectric resonators 366 may comprise a hole 365 in the axial center of the dielectric resonator 366.

In an embodiment, the dielectric resonators 366 may have a first width W1, and the cavities 367 may have a second width W2. The first width W1 of the dielectric resonator 366 is smaller than the second width W2 of the cavities 367. The difference in the widths provides a gap G between a sidewall of the dielectric resonators 366 and a sidewall of the cavity 367. In the illustrated embodiment, each of the dielectric resonators 366 are shown as having a uniform width W1. However, it is to be appreciated that not all dielectric resonators 366 of a source array 350 need to have the same dimensions.

Referring now to FIG. 3D, a cross-sectional illustration of a processing tool 300 that includes an assembly 370 is shown, in accordance with an embodiment. In an embodiment, the processing tool comprises a chamber 378 that is sealed by an assembly 370. For example, the assembly 370 may rest against one or more O-rings 303 to provide a vacuum seal to an interior chamber volume 307 of the chamber 378. In other embodiments, the assembly 370 may interface with the chamber 378. That is, the assembly 370 may be part of a lid that seals the chamber 378. In an embodiment, the processing tool 300 may comprise a plurality of processing volumes (which may be fluidically coupled together), with each processing volume having a different assembly 370. In an embodiment, a chuck 379 or the like may support a substrate 374. The substrate 374 may be a distance D from the assembly 370. In an embodiment, the interior chamber volume 307 may be suitable for delivering microwave energy to a process gas disposed within the chamber 378. That is, the chamber 378 may be a vacuum chamber.

In an embodiment, the assembly 370 comprises a source array 350 and a housing 372. The source array 350 may comprise a dielectric plate 360 and a plurality of dielectric resonators 366 extending up from the dielectric plate 360. Cavities 367 into the dielectric plate 360 may surround each of the dielectric resonators 366. Sidewalls of the cavity 367 are separated from the sidewall of the dielectric resonator 366 by a gap G. The dielectric plate 360 and the dielectric resonators 366 of the source array 350 may be a monolithic structure (as shown in FIG. 3D), or the dielectric plate 360 and the dielectric resonators 366 may be discrete components.

The housing 372 include rings 331 that fit into the gaps G. In an embodiment, the rings 331 and the conductive body 373 of the housing 372 are a monolithic structure (as shown in FIG. 3D), or the conductive body 373 and the rings 331 may be discrete components. The housing 372 may having openings sized to receive the dielectric resonators 366. In an embodiment, monopole antennas 388 may extend into holes in the dielectric resonators 366. The monopole antennas 388 are each electrically coupled to power sources (e.g., high-frequency emission modules 305).

While the foregoing is directed to embodiments of the present disclosure, other and further embodiments of the disclosure may be devised without departing from the basic scope thereof, and the scope thereof is determined by the claims that follow.

We claim:

1. A method of processing a substrate, comprising:
positioning a substrate within a processing chamber that comprises a microwave source;
flowing a process gas that comprising hydrogen into the processing chamber;
delivering microwave energy to the processing gas, wherein delivering the microwave energy to the process gas does not generate a plasma in the processing chamber, and
wherein
a substrate temperature is maintained at a temperature below approximately 300° C. while the flowing the process gas and the delivering the microwave energy; and
the flowing the process gas and the delivering microwave energy is configured to remove a halogen containing material from a surface of the substrate or a metal oxide from the surface of the substrate.

2. The method of claim 1, further comprising performing a deposition process on the substrate to form one or more metal layers over the substrate after delivering the microwave energy to the process gas.

3. The method of claim 1, further comprising:
before positioning the substrate within the processing chamber, exposing the substrate to a carbon removing pretreatment process.

4. The method of claim 3, wherein the carbon removing pretreatment process includes delivering hydrogen radicals to the substrate using a remote plasma source.

5. The method of claim 3, wherein exposing the substrate to the carbon removing pretreatment process occurs in a first chamber that does not comprise the microwave source.

6. The method of claim 1, wherein the microwave energy excites the process gas and removes contaminants from a surface of the substrate.

7. The method of claim 6, wherein the contaminants include halogens or metal oxides.

8. A method of processing a semiconductor structure formed in a substrate, comprising:
exposing a feature formed within a substrate to a preclean process, wherein the preclean process comprises:
positioning a substrate within a processing chamber that comprises a microwave source;
flowing a process gas that comprising hydrogen into the processing chamber;
delivering microwave energy, from the microwave source, to the processing gas, wherein delivering the microwave energy to the process gas does not generate a plasma in the processing chamber; and
maintaining the substrate at a temperature below 300° C.

9. The method of claim 8, further comprising performing a deposition process on the feature to form one or more metal layers after exposing the feature to the preclean process.

10. The method of claim 8, further comprising:
before exposing the feature to the preclean process, exposing the feature to a carbon removing pretreatment process.

11. The method of claim 10, wherein the carbon removing pretreatment process includes delivering hydrogen radicals to the substrate using a remote plasma source.

12. The method of claim 10, wherein exposing the substrate to the carbon removing pretreatment process occurs in a first chamber that does not comprise the microwave source.

13. The method of claim 8, wherein the microwave energy excites the process gas and removes contaminants from a surface of the feature.

14. The method of claim 13, wherein the contaminants include halogens or metal oxides.

15. A microwave processing tool comprising:
a chamber;
a chuck disposed in the chamber;
an array of modular high-frequency emission modules coupled to the chamber; and
a controller configured to cause the microwave processing tool to:
position a substrate within a processing chamber that comprises a microwave source;
flow a process gas that comprising hydrogen into the processing chamber;
deliver microwave energy to the processing gas, wherein delivering the microwave energy to the process gas does not generate a plasma in the processing chamber.

16. The microwave processing tool of claim 15, wherein delivering microwave energy to the processing gas comprises:
maintaining a substrate temperature below approximately 300° C. while the flowing the process gas and the delivering the microwave energy; and
the flowing the process gas and the delivering microwave energy is configured to remove a halogen containing material from a surface of the substrate and/or a metal oxide from the surface of the substrate.

17. The microwave processing tool of claim 15, wherein each of the array of modular high-frequency emission modules comprises an oscillator module, an amplification module, and an applicator integrated into a source array of the chamber.

18. The microwave processing tool of claim 17, wherein the oscillator module generates high-frequency electromagnetic radiation that is transmitted to the amplification module.

19. The microwave processing tool of claim 18, wherein the applicator couples the electromagnetic radiation to processing gases in the chamber without forming plasma.

20. The microwave processing tool of claim 17, wherein the amplification module comprises a pre-amplifier and a main power amplifier, each coupled to a power supply, the amplification operating in a pulse mode.
